(19) United States
(12) Patent Application Publication
(10) Pub. No.: US 2026/0353797 A1
(43) Pub. Date: Nov. 5, 2026

(54) SEMICONDUCTOR DEVICE INCLUDING SOURCE CONNECTION STRUCTURE

(71) Applicant: Samsung Electronics Co., Ltd., Suwon-si (KR)

(72) Inventors: Sangwoo Han, Suwon-si (KR); Jaehyun Park, Suwon-si (KR); Juhun Park, Suwon-si (KR); Jaewon Jeong, Suwon-si (KR)

(73) Assignee: Samsung Electronics Co., Ltd., Suwon-si (KR)

(21) Appl. No.: 19/420,615

(22) Filed: Dec. 15, 2025

(30) Foreign Application Priority Data
May 2, 2025 (KR) 10-2025-0058061

(51) Int. Cl. H10D 84/90

(52) U.S. Cl. CPC H10D 84/975; H10D 84/953; H10D 84/959

(57) ABSTRACT

A semiconductor device includes first source/drain regions spaced apart from one another in a first direction, first gate structures spaced apart from one another in the first direction and extending in a second direction, substantially perpendicular to the first direction, second source/drain regions spaced apart from the first source/drain regions, respectively, in a third direction, substantially perpendicular to the first and second directions, second gate structures spaced apart from the first gate structures, respectively, in the third direction and extending in the second direction, and a source connection structure connecting one of the first source/drain regions and one of the second source/drain regions to one another, wherein the source connection structure overlaps the second source/drain regions and the second gate structures in plan view.

### CROSS-REFERENCE TO RELATED APPLICATIONS

This present application claims priority to and the benefit 35 U.S.C. § 119(a)-(d) of Korean Patent Application No. 10-2025-0058061, filed on May 2, 2025, in the Korean Intellectual Property Office, the entire disclosure of which is incorporated herein by reference.

### BACKGROUND

The present disclosed concepts relate to a semiconductor device.

In line with the growing demand for high performance, high speed, and/or multi-functionality of semiconductor devices, the integration of semiconductor devices has increased. In order to overcome the limitations of operating characteristics due to a size reduction of planar metal oxide semiconductor field effect transistors (MOSFETs), efforts have been made to develop semiconductor devices including transistors having a three-dimensional channel structure. In addition, in accordance with the trend of high integration of semiconductor devices, a three-dimensional stacked FET (3DSFET) in which stacks transistors are vertically stacked has been proposed.

### SUMMARY

Aspects of the present disclosed concepts are to provide a semiconductor device having improved integration and electrical characteristics.

According to aspects of the present disclosed concepts, a semiconductor device includes: a first semiconductor structure; and a second semiconductor structure on the first semiconductor structure, wherein the first semiconductor structure includes: an active region extending in a first direction; first gate electrodes extending on the active region in a second direction, intersecting the first direction; a plurality of first channel layers spaced apart from one another on the active region in a third direction, substantially perpendicular to the first and second directions, and respectively surrounded by the first gate electrodes; first source/drain regions connected to the plurality of first channel layers on both sides of the first gate electrodes; a first bonding insulating layer on the first gate electrodes; first source contact plugs connected to the first source/drain regions and extending in the third direction; a first interconnection line extending through the first bonding insulating layer in the first direction and connected to one of the first source contact plugs; and first gate contact plugs connected to the first gate electrodes and extending in the third direction, and wherein the second semiconductor structure includes: second gate electrodes extending in the second direction; a plurality of second channel layers spaced apart from one another in the third direction and respectively surrounded by the second gate electrodes; second source/drain regions connected to the plurality of second channel layers on both sides of the second gate electrodes; a second bonding insulating layer disposed below the second gate electrodes and bonded to the first bonding insulating layer; second source contact plugs connected to upper regions of the second source/drain regions and extending in the third direction; a source connection plug connecting a lower region of one of the second source/drain regions to the first interconnection line and extending in the third direction through the second bonding insulating layer; and second gate contact plugs connected to the second gate electrodes and the first gate contact plugs and extending in the third direction, wherein a first active structure including the plurality of first channel layers and the first source/drain regions overlaps the first interconnection line in the third direction.

According to aspects of the present disclosed concepts, a semiconductor device includes: first source/drain regions spaced apart from one another in a first direction; first gate structures spaced apart from one another in the first direction and extending in a second direction, substantially perpendicular to the first direction; second source/drain regions spaced apart from the first source/drain regions, respectively, in a third direction, substantially perpendicular to the first and second directions; second gate structures spaced apart from the first gate structures, respectively, in the third direction and extending in the second direction; and a source connection structure connecting one of the first source/drain regions and one of the second source/drain regions to one another, wherein the source connection structure overlaps the second source/drain regions and the second gate structures in plan view.

According to aspects of the present disclosed concepts, a semiconductor device includes: a first semiconductor structure; and a second semiconductor structure on the first semiconductor structure, wherein the first semiconductor structure includes: a first active structure extending in a first direction; first gate electrodes intersecting the first active structure and extending in a second direction, intersecting the first direction; and a first bonding insulating layer on the first gate electrodes, and wherein the second semiconductor structure includes: a second active structure extending in the first direction; second gate electrodes intersecting the second active structure and extending in the second direction; and a second bonding insulating layer disposed below the second gate electrodes and bonded to the first bonding insulating layer, and the semiconductor device further includes: gate connection structures electrically connecting the first gate electrodes to the second gate electrodes, respectively; and a source connection structure electrically connecting a region of the first active structure to a region of the second active structure, wherein the source connection structure is disposed between the first active structure and the second active structure in a third direction, substantially perpendicular to the first direction and the second direction, and overlaps the first active structure and the second active structure in plan view.

### BRIEF DESCRIPTION OF THE DRAWINGS

The and other aspects, features, and advantages of the present disclosed concepts will be more clearly understood from the following detailed description, taken in conjunction with the accompanying drawings, in which:

FIG. 1 is a circuit diagram of a semiconductor device according to embodiments;

FIG. 2 is a plan view illustrating a semiconductor device according to embodiments;

FIGS. 3A and 3B are cross-sectional views illustrating a semiconductor device according to embodiments;

FIG. 4 is a perspective view illustrating a semiconductor device according to embodiments;

FIGS. 5A and 5B are perspective views illustrating semiconductor devices according to embodiments;

FIGS. 6A and 6B are cross-sectional views illustrating semiconductor devices according to embodiments;

FIG. 7 is a cross-sectional view illustrating a semiconductor device according to embodiments; and

FIGS. 8A to 8I are diagrams illustrating a process sequence for explaining a method of manufacturing a semiconductor device according to embodiments.

### DETAILED DESCRIPTION

Hereinafter, embodiments of the present disclosed concepts will be described with reference to the attached drawings. Hereinafter, terms, such as ‘above,’ ‘upper portion,’ ‘upper surface,’ ‘below,’ ‘lower portion, ‘lower surface,’ ‘side surface,’ or the like, unless otherwise stated, may be understood to be referred to, based on the drawings.

The embodiments described below may be combined with one another and described as one embodiment.

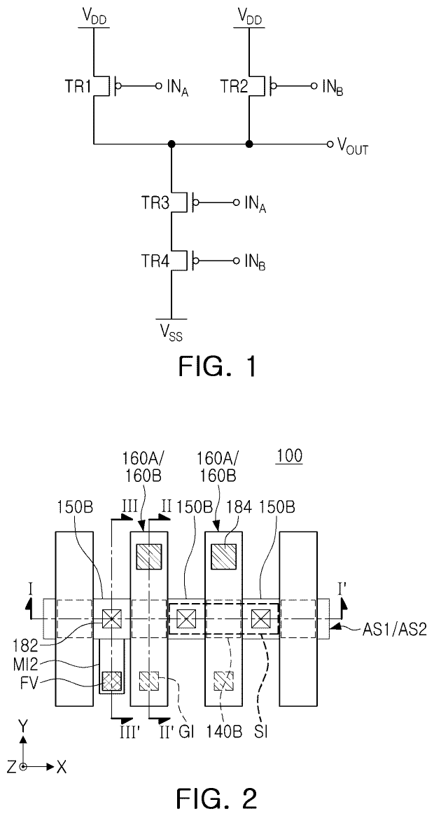

FIG. 1 is a circuit diagram of a semiconductor device according to embodiments.

Referring to FIG. 1, the semiconductor device may include a NAND circuit. The NAND circuit may include first and second pull-up devices TR1 and TR2 connected in parallel with one another and first and second pull-down devices TR3 and TR4 connected in series with one another. The first and second pull-up devices TR1 and TR2 may be connected to a first power supply V_{DD}. The second pull-down device TR4 may be connected to a second power supply V_{SS}.

Gates of the first pull-up device TR1 and the first pull-down device TR3 may be connected to one another to provide a first input terminal IN_{A}, and gates of the second pull-up device TR2 and the second pull-down device TR4 may be connected to one another to provide a second input terminal IN_{B}. One of source/drain regions of each of the first and second pull-up devices TR1 and TR2 and one of the source/drain regions of the third pull-down device TR3 may be connected to one another to provide an output terminal V_{OUT}.

However, the NAND circuit as illustrated in FIG. 1 is only an example of the circuits included in the embodiments, and the semiconductor device may provide various circuits.

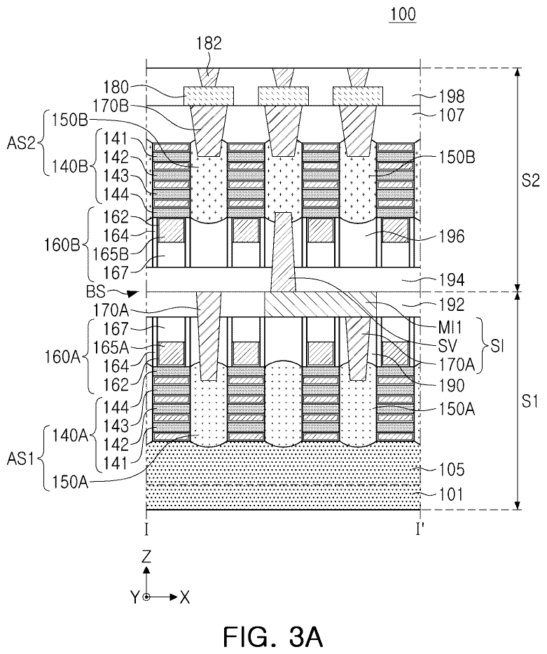

FIG. 2 is a plan view illustrating a semiconductor device according to embodiments. In FIG. 2, only some components of the semiconductor device are illustrated.

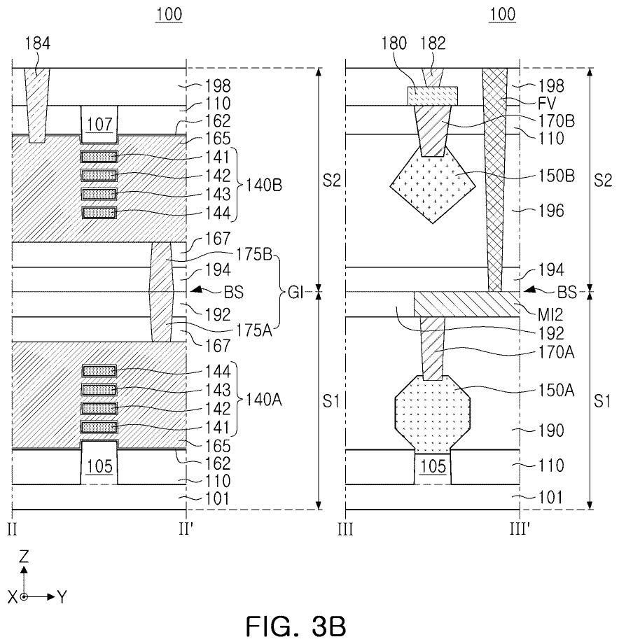

FIGS. 3A and 3B are cross-sectional views illustrating the semiconductor device according to embodiments. FIG. 3A illustrates a cross-section of the semiconductor device of FIG. 2 taken along line I-I′, and FIG. 3B illustrates cross-sections of the semiconductor device of FIG. 2 taken along lines II-II′ and III-III′.

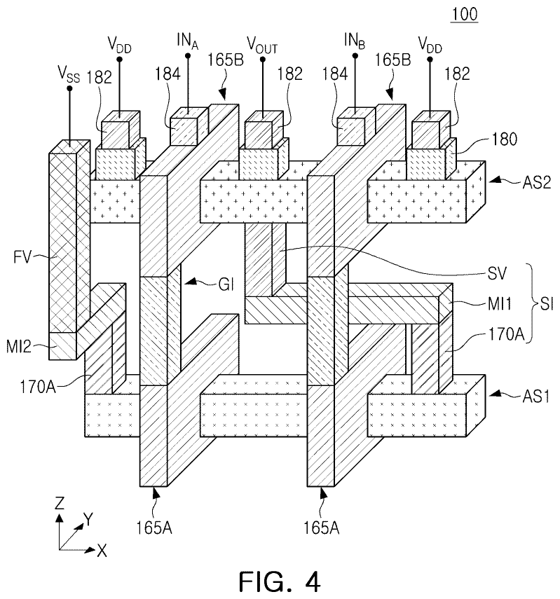

FIG. 4 is a perspective view illustrating the semiconductor device according to embodiments.

Referring to FIGS. 2 to 4, a semiconductor device 100 includes first and second semiconductor structures S1 and S2 that are bonded vertically. Each of the first and second semiconductor structures S1 and S2 may include a plurality of transistors, and the transistors of the first semiconductor structure S1 and the transistors of the second semiconductor structure S2 may be electrically connected to one another. The first and second semiconductor structures S1 and S2 may include transistors of different conductivity types. For example, the first semiconductor structure S1 may be an nFET region and the second semiconductor structure S2 may be a pFET region.

The semiconductor device 100 of the present embodiment may include transistors forming the NAND circuit of FIG. 1. The first semiconductor structure S1 may include the first and second pull-down devices TR3 and TR4 of FIG. 1, and the second semiconductor structure S2 may include the first and second pull-up devices TR1 and TR2 of FIG. 1. However, in some embodiments, the first and second semiconductor structures S1 and S2 may be regions in which transistors having the same conductivity type but different electrical characteristics are arranged.

The first semiconductor structure S1 may include a substrate 101 including an active region 105, first gate structures 160A extending to intersect the active region 105 and respectively including first gate electrodes 165A, first channel structures 140A arranged to be vertically spaced apart from one another on the active region 105 and each including first to fourth channel layers 141, 142, 143, and 144, first source/drain regions 150A in contact with the first channel structures 140A, first source contact plugs 170A connected to the first source/drain regions 150A, first and second interconnection lines MI1 and MI2 connected to the first source contact plugs 170A, and first gate contact plugs 175A connected to the first gate electrodes 165A. The first semiconductor structure S1 may further include a device isolation layer 110, a first interlayer insulating layer 190, and a first bonding insulating layer 192.

The second semiconductor structure S2 may include a base insulating layer 107, second gate structures 160B respectively including second gate electrodes 165B, second channel structures 140B arranged to be vertically spaced apart from one another on the base insulating layer 107 and each including first to fourth channel layers 141, 142, 143, and 144, second source/drain regions 150B in contact with the second channel structures 140B, second source contact plugs 170B respectively connected to the second source/drain regions 150B, upper interconnection lines 180 respectively connected to the second source contact plugs 170B, first upper contacts 182 respectively on the upper interconnection lines 180, a source connection plug SV connected to a lower region of the second source/drain region 150B, second gate contact plugs 175B connected to the second gate electrodes 165B, and second upper contacts 184 connected to the second gate electrodes 165B. The second semiconductor structure S2 may further include a device isolation layer 110, a second bonding insulating layer 194, a second interlayer insulating layer 196, a third interlayer insulating layer 198, and a through-via FV.

The semiconductor device 100 may include transistors having a 3-dimensional stacked field effect transistor (3DSFET) structure in which transistors of the first semiconductor structure S1 and transistors of the second semiconductor structure S2 are vertically stacked. In the semiconductor device 100, the first and second gate electrodes 165A and 165B may be arranged between the first to fourth channel layers 141, 142, 143, and 144 of the first and second channel structures 140A and 140B and above and below the first and second channel structures 140A and 140B. Accordingly, the semiconductor device 100 may include transistors having a multi-bridge channel FET (MBCFET™) structure, a gate-all-around type field effect transistor.

The substrate 101 may have an upper surface extending in the X-direction and the Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include the active region 105 defined in an upper region by the device isolation layer 110. The active region 105 may be disposed to extend in a first direction, for example, the X-direction. Depending on the technology, the active region 105 may also be referred to as a separate component from the substrate 101. The active region 105 may partially protrude above the device isolation layer 110 from below the first gate structures 160A, and a portion of an upper surface of the active region 105 may be located on a higher level than an upper surface of the device isolation layer 110. The active region 105 may be formed of the same material as that of the substrate 101 or may include an epitaxial layer grown from the substrate 101. However, the active region 105 may be partially recessed on both sides of the first gate structures 160A, and the first source/drain regions 150A may be arranged on the active region 105.

The active region 105 may each include a well region including impurities. For example, the well region may include p-type impurities, such as boron (B), gallium (Ga), or aluminum (Al), or n-type impurities, such as phosphorus (P), arsenic (As), or antimony (Sb). The well region may be located at a predetermined depth from the upper surface of each of the active regions 105, for example. However, in some embodiments, the active region 105 may not include impurities.

The device isolation layer 110 may define the active region 105 within the substrate 101. The device isolation layer 110 may be formed, for example, by a shallow trench isolation (STI) process. The device isolation layer 110 may expose at least the upper surface of the active region 105 and may also expose a portion of the upper surface of the active region 105. According to embodiments, the device isolation layer 110 may have a curved upper surface to have a higher level as being closer to the active region 105. The device isolation layer 110 may be formed of an insulating material. The device isolation layer 110 may be, for example, an oxide, a nitride, or combinations thereof.

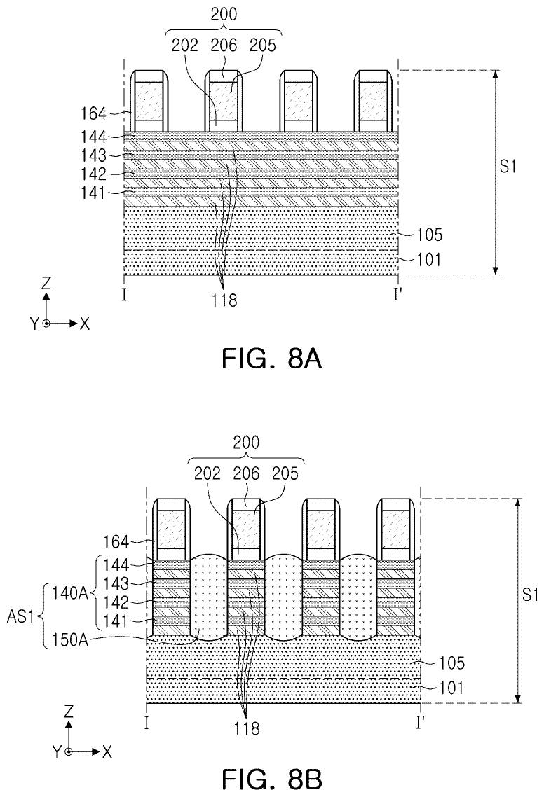

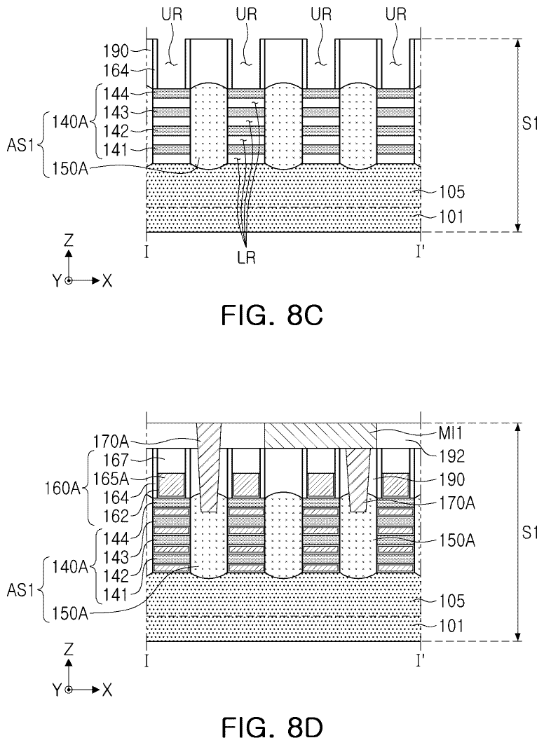

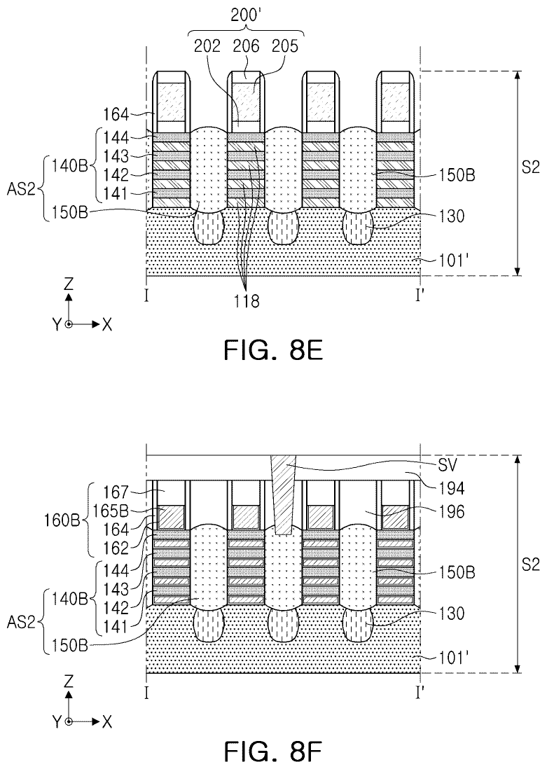

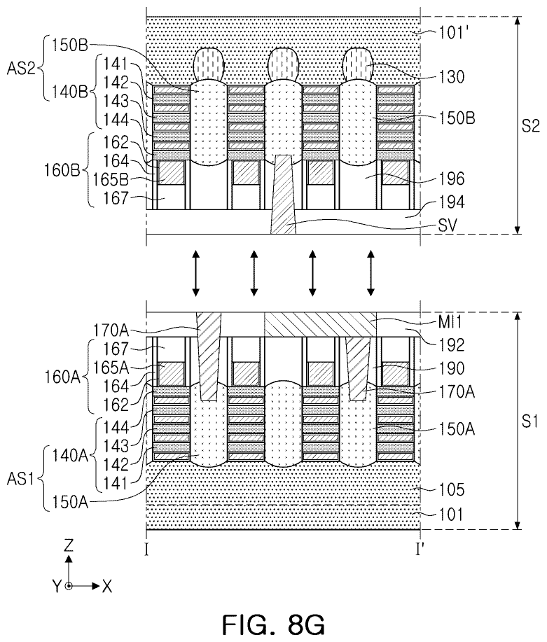

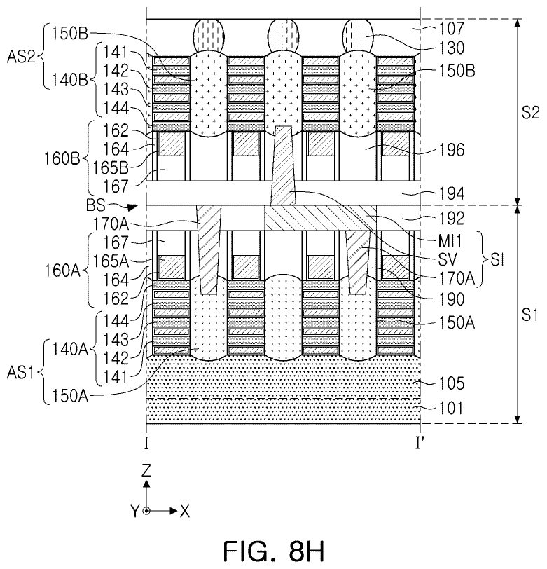

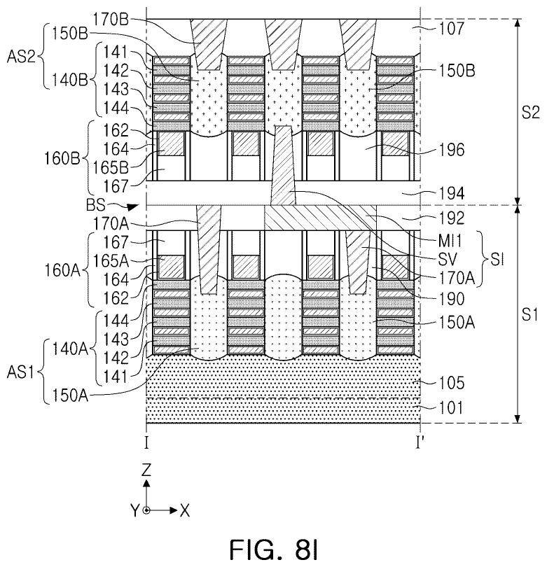

The base insulating layer 107 may be a layer formed by removing and/or oxidizing a base substrate 101′ (see FIG. 8E) formed of a semiconductor material during a manufacturing process. The base insulating layer 107 may be disposed on the second channel structures 140B and the second source/drain regions 150B and may be disposed to fill the space between the second source contact plugs 170B.

The base insulating layer 107 may be formed of an insulating material and may include, for example, an oxide, a nitride, or combinations thereof. In some embodiments, the base insulating layer 107 may include the same material as that of the device isolation layer 110 and/or the third interlayer insulating layer 198, in which case the interfaces with the device isolation layer 110 and/or the third interlayer insulating layer 198 may or may not be apparent. According to embodiments, the base insulating layer 107 may include a plurality of insulating layers.

In the first semiconductor structure S1 and the second semiconductor structure S2, some components may be arranged symmetrically vertically with respect to a bonding surface BS. The bonding surface BS may be an interface between the first semiconductor structure S1 and the second semiconductor structure S2 and may be an interface between a first bonding insulating layer 192 and the second bonding insulating layer 194. For example, the first gate structures 160A, the first channel structures 140A, and the first source/drain regions 150A of the first semiconductor structure S1 may be arranged to be symmetrical with the second gate structures 160B, the second channel structures 140B, and the second source/drain regions 150B of the second semiconductor structure S2 based on the bonding surface BS. Accordingly, unless otherwise stated, descriptions of any one of the components of the first semiconductor structure S1 may be equally applied to the corresponding component of the second semiconductor structure S2. However, the components arranged symmetrically with one another do not necessarily have the same shape and may have the same shape or different shapes.

The first gate structures 160A may be arranged to extend in one direction, for example, in the Y-direction, on the active region 105. The first gate structures 160A may be arranged to be spaced apart from one another in the X-direction. Channel regions of the transistors may be formed in the first channel structures 140An intersecting the first gate electrodes 165A of the first gate structures 160A. Each of the first gate structures 160A may include gate dielectric layers 162, gate spacer layers 164, a first gate electrode 165A, and a gate capping layer 167.

The second gate structures 160B may be arranged to extend in one direction, for example, in the Y-direction, on the lower surface of the base insulating layer 107. The second gate structures 160B may be arranged to at least partially overlap the first gate structures 160A in the Z-direction. In the present specification, overlapping in the Z-direction may have the same meaning as overlapping in plan view, such as in FIG. 2. For example, the second gate structures 160B may have the same width as those of the first gate structures 160A in the X-direction and may be arranged to overlap the first gate structures 160A entirely in the Z-direction. The second gate structures 160B may be arranged to be spaced apart from one another in the X-direction. Channel regions of transistors may be formed in the second channel structures 140B intersecting the second gate electrodes 165B of the second gate structures 160B. The second gate structures 160B may each include gate dielectric layers 162, gate spacer layers 164, a second gate electrode 165B, and a gate capping layer 167.

In the first semiconductor structure S1, the gate dielectric layers 162 may be arranged between the active region 105 and the first gate electrode 165A and between the first channel structure 140A and the first gate electrode 165A and may be arranged to cover at least a portion of the surfaces of the first gate electrode 165A. For example, the gate dielectric layers 162 may be arranged to surround all surfaces except the top surface of the first gate electrode 165A. The gate dielectric layers 162 may extend between the first gate electrode 165A and the gate spacer layers 164, but are not limited thereto. Similarly, in the second semiconductor structure S2, the gate dielectric layers 162 may be arranged between the base insulating layer 107 and the second gate electrode 165B and between the second channel structure 140B and the second gate electrode 165B.

The gate dielectric layer 162 may include an oxide, a nitride, or a high-k material. The high-k material may refer to a dielectric material having a higher dielectric constant than that of silicon oxide (SiO₂). The high-k material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to embodiments, the gate dielectric layer 162 may be formed of a multilayer structure.

The first gate electrode 165A and the second gate electrode 165B may include a conductive material, for example, a metal nitride, such as titanium nitride (TiN), tantalum nitride (TaN), or tungsten nitride (WN), and/or a metal material, such as aluminum (Al), tungsten (W), or molybdenum (Mo), or a semiconductor material, such as doped polysilicon. The first gate electrode 165A and the second gate electrode 165B may include the same or different materials. For example, the first gate electrode 165A may include an n-metal, and the second gate electrode 165B may include a p-metal. According to embodiments, the first gate electrode 165A and the second gate electrode 165B may be formed to have a multilayer structure. The first gate electrode 165A may be connected to the first gate contact plug 175A through an upper surface thereof. The second gate electrode 165B may be connected to the second gate contact plug 175B through a lower surface thereof.

The gate spacer layers 164 may be arranged on both side surfaces of the first gate electrode 165A on the first channel structures 140A. The gate spacer layers 164 may insulate the first source/drain regions 150A and the first gate electrode 165A. According to embodiments, the shape of the upper portion of the gate spacer layers 164 may vary, and the gate spacer layers 164 may be formed to have a multilayer structure. Similarly, the gate spacer layers 164 may be arranged on both side surfaces of the second gate electrode 165B below the second channel structures 140B. The gate spacer layers 164 may include at least one of an oxide, a nitride, or an oxynitride and may be formed of, for example, a low-k film.

The gate capping layer 167 may be disposed on the first gate electrode 165A. In some embodiments, a lower surface of the gate capping layer 167 may have a downwardly convex shape. Similarly, the gate capping layer 167 may be disposed below the second gate electrode 165B. The gate capping layer 167 may include an insulating material and may include at least one of, for example, an oxide, a nitride, or an oxynitride.

The first channel structures 140A may be arranged in regions on the active region 105 in which the active region 105 intersects the first gate structures 160A. The second channel structures 140B may be arranged in regions intersecting the second gate structures 160B below the base insulating layer 107. The first channel structures 140A may form a first active structure AS1 together with the first source/drain regions 150A, and the second channel structures 140B may form a second active structure AS2 together with the second source/drain regions 150B. The first active structure AS1 may be described as further including the active region 105. The first and second active structures AS1 and AS2 may extend in the X-direction and may be spaced apart from one another in the Z-direction. The first active structure AS1 and the second active structure AS2 may be arranged to a least partially overlap in the Z-direction. For example, the first active structure AS1 and the second active structure AS2 may have the same width in the Y-direction and may be arranged to overlap one another entirely in the Z-direction.

Each of the first and second channel structures 140A and 140B may include first to fourth channel layers 141, 142, 143, and 144, two or more plurality of channel layers, arranged to be spaced apart from one another in a direction, perpendicular to the upper surface of the active region 105, for example, in the Z-direction. The first to fourth channel layers 141, 142, 143, and 144 may be connected to the first and second source/drain regions 150A and 150B, while being spaced apart from the upper surface of the active region 105. The first to fourth channel layers 141, 142, 143, and 144 may have a width equal to or smaller than that of the active region 105 in the Y-direction and may have a width equal to or similar to that of the first and second gate structures 160A and 160B in the X-direction. The width of the first to fourth channel layers 141, 142, 143, and 144 in the Y-direction may increase toward the lower channel layer, but is not limited thereto. The number and shape of the channel layers 141, 142, 143, and 144 of each of the first and second channel structures 140A and 140B may vary in the embodiments.

The first to fourth channel layers 141, 142, 143, and 144 may be formed of a semiconductor material and may include, for example, at least one of silicon SI, silicon germanium (SiGe), or germanium (Ge). The first to fourth channel layers 141, 142, 143, and 144 may be formed of, for example, the same material as that of the substrate 101.

The first source/drain regions 150A may be arranged to contact the first channel structures 140A on both sides of the first gate structures 160A. The first source/drain regions 150A may be arranged to cover the side surfaces of each of the first to fourth channel layers 141, 142, 143, and 144 of the first channel structures 140A in the X-direction. The upper surfaces of the first source/drain regions 150A may be disposed on the same level as or higher than that of the lower surface of the first gate electrode 165A on the first channel structures 140A, and the level may vary in embodiments.

The second source/drain regions 150B may be arranged to contact the second channel structures 140B on both sides of the second gate structures 160B. The second source/drain regions 150B may be arranged to cover the side surfaces of each of the first to fourth channel layers 141, 142, 143, and 144 of the second channel structures 140B in the X-direction.

The first and second source/drain regions 150A and 150B may include a polygonal shape region in a cross-section in the Y-direction outside the first and second gate structures 160A and 160B. The shape of the first source/drain regions 150A and the shape of the second source/drain regions 150B may be different from one another. However, in the embodiments, the shape of the first and second source/drain regions 150A and 150B is not limited to the shape illustrated in FIG. 3B and the first and second source/drain regions 150A and 150B may each have a curved polygonal shape, an elliptical shape, or a circular shape. The first source/drain regions 150A may be connected to the first source contact plugs 170A thereabove, respectively. The second source/drain regions 150B may be connected to the second source contact plugs 170B thereabove, respectively.

The first and second source/drain regions 150A and 150B may include a semiconductor material, for example, at least one of silicon (Si) or germanium (Ge) and may further include impurities. For example, the first source/drain regions 150A may have a lower concentration of germanium (Ge) than that of the second source/drain regions 150B. For example, the first source/drain regions 150A may include at least one of phosphorus (P), arsenic (As), or antimony (Sb), which are n-type impurities, and the second source/drain regions 150B may include at least one of boron (B), gallium (Ga), or indium (In), which are p-type impurities. Each of the first and second source/drain regions 150A and 150B may include a plurality of epitaxial layers having different compositions.

In some embodiments, the semiconductor device 100 may further include internal spacer layers disposed between side surfaces of the first source/drain regions 150A and/or the second source/drain regions 150B in the X-direction and the gate dielectric layers 162. The internal spacer layers may include an insulating material.

The first interlayer insulating layer 190 may be disposed on the first source/drain regions 150A, the second interlayer insulating layer 196 may be disposed below the second source/drain regions 150B, and the third interlayer insulating layer 198 may be disposed on the base insulating layer 107 and the second source contact plugs 170B. The first to third interlayer insulating layers 190, 196, and 198 may include an insulating material, for example, at least one of an oxide, a nitride, or an oxynitride and may include, for example, a low-k material. According to embodiments, at least one of the first to third interlayer insulating layers 190, 196, and 198 may include a plurality of insulating layers.

The first bonding insulating layer 192 may be disposed on the first interlayer insulating layer 190 and the first gate structures 160A, and the second bonding insulating layer 194 may be disposed below the second interlayer insulating layer 196 and the second gate structures 160B. The first and second bonding insulating layers 192 and 194 may be layers for bonding the first semiconductor structure S1 and the second semiconductor structure S2 and may be layers for dielectric-dielectric bonding. The first and second bonding insulating layers 192 and 194 may include an insulating material, for example, at least one of SiO, SiN, SiCN, SiOC, SiON, or SiOCN. In some embodiments, the first bonding insulating layer 192 and the second bonding insulating layer 194 may include different materials. For example, the first bonding insulating layer 192 may include SiO and the second bonding insulating layer 194 may include SiCN, or vice versa.

The first source contact plugs 170A may be connected to upper regions of the first source/drain regions 150A and may apply an electrical signal to the first source/drain regions 150A. The first source contact plugs 170A may penetrate through the first bonding insulating layer 192 and the first interlayer insulating layer 190. Among the first source contact plugs 170A, the first source contact plug 170A connected to the first interconnection line MI1 is disposed in a form in which an upper region thereof is removed by the first interconnection line MI1, so that a level of an upper end thereof in a final structure may be lower than those of other first source contact plugs 170A. However, in some embodiments, the first interconnection line MI1 may be disposed to be connected to the side surfaces of the first source contact plugs 170A. In this case, the levels of the upper ends of the first source contact plugs 170A may be uniform.

The second source contact plugs 170B may be connected to the upper regions of the second source/drain regions 150B and may apply an electrical signal to the second source/drain regions 150B. The second source contact plugs 170B may penetrate through the base insulating layer 107.

The first and second source contact plugs 170A and 170B may have inclined side surfaces in which the width of a lower portion thereof is narrower than the width of an upper portion thereof depending on the aspect ratio, but is not limited thereto. The relative width, height, or the like of the first and second source contact plugs 170A and 170B may vary in embodiments. The first and second source contact plugs 170A and 170B may be arranged by recessing the first and second source/drain regions 150A and 150B from the upper surfaces. The first source contact plugs 170A may extend downwardly from the upper portion, for example, below the lower surface of the uppermost fourth channel layer 144 of the first channel structure 140A, but is not limited thereto.

The source connection plug SV may be connected to a lower region of at least one of the second source/drain regions 150B. The source connection plug SV may be disposed to penetrate through the second bonding insulating layer 194 and the second interlayer insulating layer 196 and to partially recess the second source/drain regions 150B from the lower surface. The source connection plug SV may have an inclined side surface in which the width of a lower portion thereof is wider than the width of an upper portion thereof depending on the aspect ratio, but is not limited thereto.

The first gate contact plugs 175A may be connected to the upper surfaces of the first gate electrodes 165A by penetrating through the first bonding insulating layer 192 and the gate capping layer 167. The second gate contact plugs 175B may be connected to the lower surfaces of the second gate electrodes 165B by penetrating through the second bonding insulating layer 194 and the gate capping layer 167. The first gate contact plugs 175A may be connected to the second gate contact plugs 175B, respectively, to electrically connect the first gate electrode 165A and the second gate electrode 165B spaced apart from one another in the Z-direction. The first and second gate contact plugs 175A and 175B connected to one another may form a gate connection structure GI.

The gate connection structure GI may overlap the first and second gate electrodes 165A and 165B in the Z-direction, for example, entirely. In the present embodiment, the gate connection structure GI may be disposed in a region overlapping the device isolation layers 110 in the Z-direction. The first gate contact plugs 175A and the second gate contact plugs 175B may have a shape in which the slopes of the side surfaces thereof are symmetrical with respect to the bonding surface BS. In some embodiments, the first and second gate contact plugs 175A and 175B may be disposed to partially recess the first and second gate electrodes 165A and 165B.

The first and second source contact plugs 170A and 170B, the source connection plug SV, and the first and second gate contact plugs 175A and 175B may include a conductive material, for example, a metal material, such as aluminum (Al), tungsten (W), or molybdenum (Mo). According to embodiments, the first and second source contact plugs 170A and 170B and the source connection plug SV may include a metal-semiconductor compound layer, such as a metal silicide layer, disposed at an interface with the first and second source/drain regions 150A and 150B and may further include a barrier layer forming side surfaces of the first and second source contact plugs 170A and 170B and the source connection plug SV and extending into the metal-semiconductor compound layer. Similarly, the first and second gate contact plugs 175A and 175B may further include a metal-semiconductor compound layer and a barrier layer located at an interface with the first and second gate electrodes 165A and 165B. The barrier layer may include, for example, a metal nitride, such as titanium nitride (TiN), tantalum nitride (TaN), or tungsten nitride (WN).

The first and second interconnection lines MI1 and MI2 may be connected to the first source contact plugs 170A and may extend within the first bonding insulating layer 192 in a horizontal direction. In embodiments, the first and second interconnection lines MI1 and MI2 may be arranged to fully penetrate through the first bonding insulating layer 192 or partially penetrate through the first bonding insulating layer 192 from the upper surfaces thereof.

The first interconnection line MI1 may extend in the X-direction to connect one of the first source contact plugs 170A to the source connection plug SV. The first interconnection line MI1 may overlap the first and second active structures AS1 and AS2 in the plan view of FIG. 2. As illustrated in FIGS. 3A and 4, the first interconnection line MI1 may be disposed to extend parallel to the first and second active structures AS1 and AS2 between the first active structure AS1 and the second active structure AS2 spaced apart from one another in the Z-direction. The first interconnection line MI1 may also overlap the active region 105 in the plan view. The first interconnection line MI1 may extend between the first gate electrode 165A and the second gate electrode 165B spaced apart from one another in the Z-direction, as illustrated in FIGS. 3A and 4.

The first interconnection line MI1 may form a source connection structure SI together with the first source contact plugs 170A and the source connection plug SV connected thereto. The source connection structure SI may electrically connect a region of the first active structure AS1 to a region of the second active structure AS2. In the present embodiment, the source connection structure SI may electrically connect the first source/drain region 150A and the second source/drain region 150B not overlapping one another in the Z-direction. The source connection structure SI may, for example, connect an upper region of the rightmost first source/drain region 150A of the first semiconductor structure S1 and a lower region of the second source/drain region 150B at the center of the second semiconductor structure S2 in FIG. 3A. The entire source connection structure SI may overlap the first and second active structures AS1 and AS2 in the plan view of FIG. 2. The source connection structure SI may overlap the first source/drain regions 150A and the first gate structures 160A on the plan view. The source connection structure SI may overlap the second source/drain regions 150B and the second gate structures 160B on the plan view.

The second interconnection line MI2 may extend in the Y-direction to connect one of the first source contact plugs 170A to the through-via FV. The second interconnection line MI2 may extend in the Y-direction from a region overlapping the first and second active structures AS1 and AS2 between the first and second gate structures 160A and 160B adjacent in the X-direction in the plan view of FIG. 2 and may extend outwardly of the first and second active structures AS1 and AS2.

The upper interconnection lines 180 and the first upper contacts 182 may be sequentially arranged on the second source contact plugs 170B to form an electrical path. The upper interconnection lines 180 and the first upper contacts 182 may be arranged within the third interlayer insulating layer 198. However, in embodiments, the interconnection structure electrically connected to the second source contact plugs 170B may vary, including vias and lines.

The second upper contacts 184 may be connected to upper regions of the second gate electrodes 165B. As illustrated in FIG. 3B, the second upper contacts 184 may be arranged to penetrate through the third interlayer insulating layer 198, the device isolation layer 110, and the gate dielectric layer 162. The through-via FV may penetrate through the entire second semiconductor structure S2 from the upper surface to the lower surface thereof and be connected to the second interconnection line MI2. The upper end of the through-via FV may be located on a higher level than that of the upper ends of the second source contact plugs 170B. However, in some embodiments, the through-via FV may not penetrate through the entire second semiconductor structure S2, and the upper end of the through-via FV may be located on the same level as that of the upper ends of the second source contact plugs 170B or may be located within the third interlayer insulating layer 198. Additional vias and interconnection lines may be further arranged on the first upper contacts 182 and the through-via FV.

As illustrated in FIG. 4, the first upper contacts 182 on both sides of the first upper contacts 182 may be connected to the first power supply V_{DD}, and the first upper contact 182 in the center may be connected to an output terminal V_{OUT}. The second upper contacts 184 may be connected to the first input terminal IN_{A} and the second input terminal IN_{B}, respectively, and the through-via FV may be connected to the second power supply V_{SS}.

The first and second interconnection lines MI1 and MI2, the upper interconnection lines 180, the first upper contacts 182, the second upper contacts 184, and the through-via FV may include at least one of a conductive material, for example, tungsten (W), copper (Cu), aluminum (Al), cobalt (Co), ruthenium (Ru), titanium (Ti), or molybdenum (Mo).

The semiconductor device 100 may have a minimized planar area based on the first and second active structures AS1 and AS2 extending in the X-direction and the first and second gate electrodes 165A and 165B extending in the Y-direction while intersecting the first and second active structures AS1 and AS2, as illustrated in FIGS. 2 and 4. Among the components electrically connecting the transistors of the first semiconductor structure S1 and the transistors of the second semiconductor structure S2, the gate connection structure GI may overlap the first and second gate electrodes 165A and 165B, and the source connection structure SI may overlap the first and second active structures AS1 and AS2. As illustrated in the plan view of FIG. 2, all other components except the second interconnection line MI2 and the through-via FV may be arranged to overlap the first and second active structures AS1 and AS2 and the first and second gate structures 160A and 160B.

By this arrangement, the integration degree of the semiconductor device 100 may be improved, and the length of the interconnection structure may be reduced, thereby minimizing the resistance. In particular, the planar area of the semiconductor device 100 in the Y-direction may be minimized. In addition, since the semiconductor device 100 is formed by bonding the first semiconductor structure S1 and the second semiconductor structure, the manufacturing process for the nFET and pFET regions may be performed separately, so that materials optimized for each device may be selected or processes may be performed, so that the electrical characteristics may be improved.

In the description of the embodiments below, the redundant descriptions as those given above with reference to FIGS. 2 to 4 will be omitted.

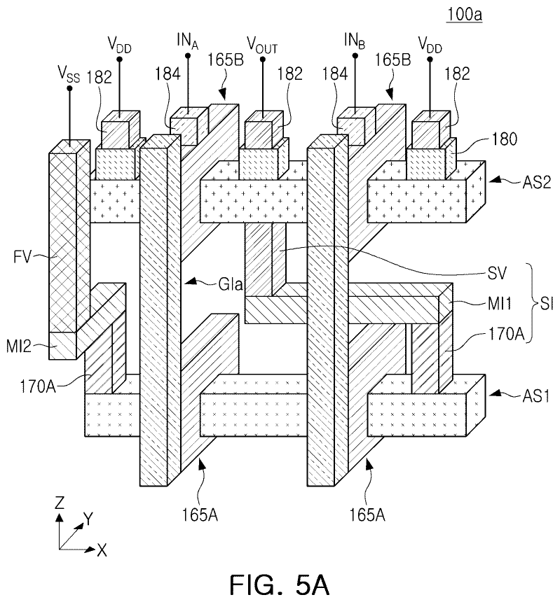

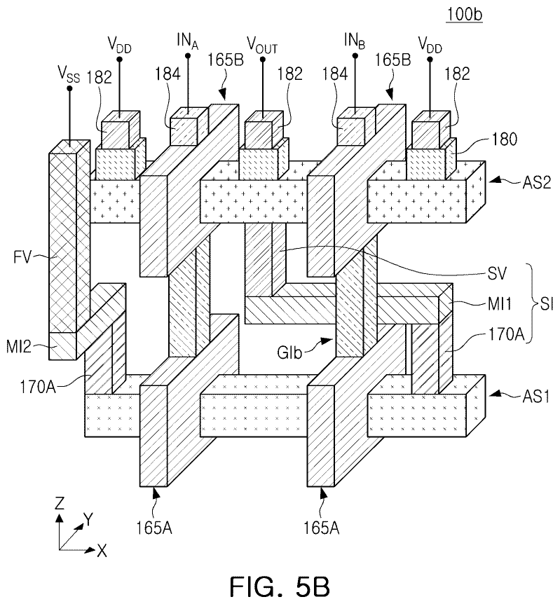

FIGS. 5A and 5B are perspective views illustrating semiconductor devices according to embodiments.

Referring to FIG. 5A, in the semiconductor device 100a, unlike the embodiments of FIGS. 2 to 4, a gate connection structure GIa may extend vertically from one side of the first and second gate electrodes 165A and 165B. The gate connection structure GIa may contact the side surfaces of the first and second gate electrodes 165A and 165B. For example, the gate connection structure GIa may be disposed as a single gate contact plug connected to the first gate electrode 165A through the second semiconductor structure S2 from the upper surface of the second semiconductor structure S2 on the cross-sectional view of FIG. 3B. In some embodiments, the gate connection structure GIa may include first and second gate contact plugs 175A and 175B contacting side surfaces of the first and second gate electrodes 165A and 165B, respectively, and the first and second gate contact plugs 175A and 175B may be arranged to be connected to one another.

Referring to FIG. 5B, in a semiconductor device 100b, a gate connection structure GIb may be disposed to overlap the first and second active structures AS1 and AS2 in the Z-direction, unlike the embodiments of FIGS. 2 to 4. For example, the gate connection structure GIb may be disposed to overlap the first and second channel structures 140A and 140B in the Z-direction. In the present embodiment, both the gate connection structure GIb and the source connection structure SI, which are components electrically connecting the transistors of the first semiconductor structure S1 and the transistors of the second semiconductor structure S2, may be arranged to overlap the first and second active structures AS1 and AS2 in the Z-direction.

As described above with reference to FIGS. 5A and 5B, in embodiments, the gate connection structure may vary within a range in which the gate connection structure overlaps the first and second gate electrodes 165A and 165B in the Z-direction or is located on one side in the extension direction of the first and second gate electrodes 165A and 165B.

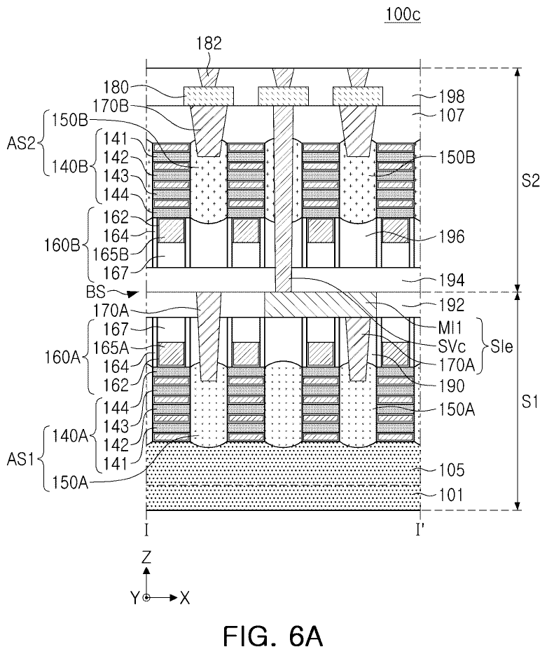

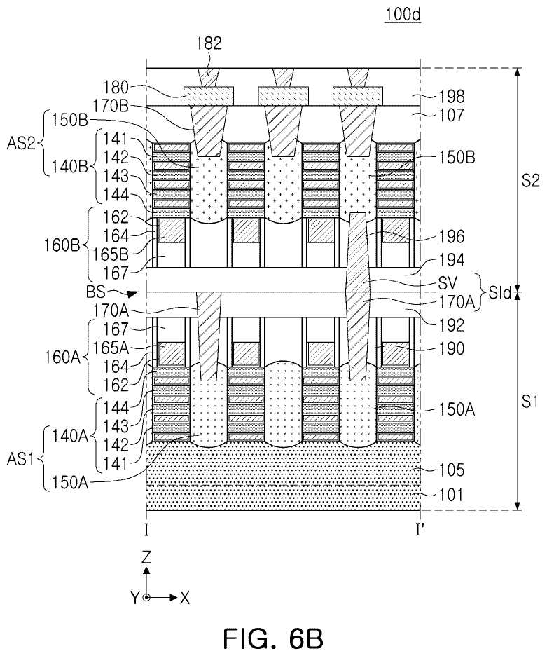

FIGS. 6A and 6B are cross-sectional views illustrating semiconductor devices according to embodiments. FIGS. 6A and 6B each illustrate a region corresponding to FIG. 3A.

Referring to FIG. 6A, in a semiconductor device 100c, a source connection plug SVc may be disposed to penetrate through the second source/drain region 150B. The source connection plug SVc may be connected to the first interconnection line MI1 at a lower end thereof and may form a source connection structure SIc together with the first interconnection line MI1 and the first source contact plug 170A connected thereto.

The second source contact plugs 170B connected to the upper regions may be disposed in a portion of the second source/drain regions 150B, and the source connection plugs SVc penetrating through the second source/drain region 150B may be disposed in a portion of the second source/drain regions 150B. However, in some embodiments, the source connection plugs SVc may be arranged instead of the second source contact plugs 170B in the entire second source/drain region 150B. In this case, considering the configuration of the circuit, the shape of the interconnection structure, such as the height of the upper ends of the first source contact plugs 170A, may be changed.

Referring to FIG. 6B, in a semiconductor device 100d, a source connection structure SId may include the first source contact plug 170A and the source connection plug SV. That is, unlike the embodiments of FIGS. 2 to 4, the source connection structure SId may not include the first interconnection line MI1. In the present embodiment, the source connection plug SV may be directly connected to the first source contact plug 170A through the lower surface thereof. In this case, in order to configure the circuit of FIG. 1, a connection shape of the transistors that are arranged vertically may be changed to be different from that of the embodiments of FIGS. 2 to 4.

As described above with reference to FIGS. 6A and 6B, in the embodiments, the structure of the source connection structure may vary within a range in which the source connection structure overlaps the first and second active structures AS1 and AS2 in the Z-direction. In addition, the embodiments of FIGS. 6A and 6B may be variously combined with the embodiments of FIGS. 5A and 5B described above.

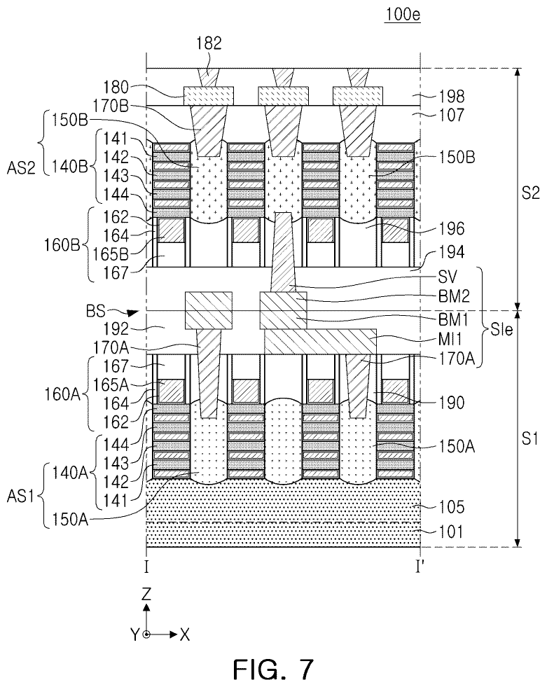

FIG. 7 is a cross-sectional view illustrating a semiconductor device according to embodiments. FIG. 7 illustrates a region corresponding to FIG. 3A.

Referring to FIG. 7, in a semiconductor device 100e, the first semiconductor structure S1 may further include first bonding pads BM1, and the second semiconductor structure S2 may further include second bonding pads BM2. The first bonding pads BM1 and the second bonding pads BM2 may be connected to one another to provide an electrical path between the first semiconductor structure S1 and the second semiconductor structure S2. The first bonding pads BM1 may be connected to the lower interconnection structure, for example, the first source contact plugs 170A and the first interconnection line MI1, and the second bonding pads BM2 may be connected to the upper interconnection structure, for example, the source connection plug SV. In the present embodiment, a source connection structure SIe may further include the first and second bonding pads BM1 and BM2.

The first and second bonding pads BM1 and BM2 may include a conductive material, for example, copper (Cu). The bonding of the first bonding pads BM1 and the second bonding pads BM2 may be, for example, copper (Cu)-to-copper (Cu) bonding, and thus, the first and second semiconductor structures S1 and S2 may be bonded by hybrid bonding including copper (Cu)-to-copper (Cu) bonding and dielectric-to-dielectric bonding.

FIGS. 8A to 8I are diagrams illustrating a sequential process of a method of manufacturing a semiconductor device according to embodiments. FIGS. 8A to 8I illustrate embodiments of a manufacturing method for manufacturing the semiconductor device of FIGS. 2 to 4. FIG. s 8A to 8I each illustrate a cross-section corresponding to FIG. 3A.

Referring to FIG. 8A, a process of forming the first semiconductor structure S1 may start. Sacrificial layers 118 and first to fourth channel layers 141, 142, 143, and 144 may be alternately stacked on the substrate 101, a preliminary active structure may be formed, and sacrificial gate structures 200 may be formed.

The substrate 101 may include silicon SI, germanium (Ge), or silicon germanium (SiGe). The substrate 101 may include a bulk wafer, an epitaxial layer, a SOI layer, or a SeOI layer.

The sacrificial layers 118 may be layers replaced with the gate dielectric layers 162 and the first gate electrodes 165A as illustrated in FIG. 3A through a subsequent process. The sacrificial layers 118 may be formed of a material having etching selectivity with respect to the first to fourth channel layers 141, 142, 143, and 144. The first to fourth channel layers 141, 142, 143, and 144 may include a material different from that of the sacrificial layers 118. The sacrificial layers 118 and the first to fourth channel layers 141, 142, 143, and 144 include a semiconductor material including, for example, at least one of silicon (Si), silicon germanium (SiGe), or germanium (Ge), but may include different materials and may or may not include impurities. For example, the sacrificial layers 118 may include silicon germanium (SiGe), and the first to fourth channel layers 141, 142, 143, and 144 may include silicon SI. The sacrificial layers 118 and the first to fourth channel layers 141, 142, 143, and 144 may be formed by performing an epitaxial growth process from the substrate 101.

Next, the first to fourth channel layers 141, 142, 143, and 144, the sacrificial layers 118, and the upper region of the substrate 101 may be patterned to form the active region 105 extending in the X-direction and a preliminary active structure, and the device isolation layer 110 (see FIG. 3B) may be formed. The device isolation layer 110 may be formed by depositing an insulating material to fill the perimeter of the preliminary active structure and then removing a portion of the deposited insulating material from above so that at least the upper surfaces of the active region 105 are exposed.

The sacrificial gate structures 200 may be sacrificial structures formed in regions in which the gate dielectric layers 162, the first gate electrodes 165A, and the gate capping layers 167 are arranged on channel structures 140 through a subsequent process, as illustrated in FIG. 3A. The sacrificial gate structures 200 may have a line shape extending in one direction, while intersecting the aforementioned preliminary active structures. The sacrificial gate structures 200 may extend, for example, in the Y-direction.

Each of the sacrificial gate structures 200 may include first and second sacrificial gate layers 202 and 205 and a mask pattern layer 206 that are sequentially stacked. The first and second sacrificial gate layers 202 and 205 may be patterned using the mask pattern layer 206. The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Referring to FIG. 8B, a portion of the preliminary active structure may be removed from the outer side of the sacrificial gate structures 200, and first source/drain regions 150A may be formed.

The sacrificial layers 118 and the first to fourth channel layers 141, 142, 143, and 144 exposed from the sacrificial gate structures 200 may be removed. In this operation, after the sacrificial layers 118 and the first to fourth channel layers 141, 142, 143, and 144 are removed, the exposed active region 105 may also be partially recessed from the upper surfaces, but are not limited thereto. By this operation, the first to fourth channel layers 141, 142, 143, and 144 may form first channel structures 140A having a limited length in the X-direction.

The first source/drain regions 150A may be formed by growing from the active region 105 by, for example, a selective epitaxial process. The first source/drain regions 150A may include impurities by in-situ doping. Accordingly, the first active structure AS1 including the first channel structures 140A and the first source/drain regions 150A alternately arranged in the X-direction may be formed. The first active structure AS1 may have a shape extending in the X-direction. Depending on the description, the first active structure AS1 may also be referred to as a component further including the active region 105.

Referring to FIG. 8C, the first interlayer insulating layer 190 may be formed, and the sacrificial layers 118 and the sacrificial gate structure 200 may be removed.

The sacrificial layers 118 and the sacrificial gate structure 200 may be selectively removed with respect to the gate spacer layers 164, the first interlayer insulating layer 190, the first channel structures 140A, and the first source/drain regions 150A. First, the sacrificial gate structures 200 may be removed to form upper gap regions UR, and then the sacrificial layers 118 exposed through the upper gap regions UR may be removed to form lower gap regions LR. For example, when the sacrificial layers 118 include silicon germanium (SiGe) and the channel structures 140 include silicon SI, the sacrificial layers 118 may be selectively removed by performing a wet etching process.

Referring to FIG. 8D, after the first gate structures 160A are formed and the first source contact plugs 170A are formed, the first interconnection line MI1 may be formed.

The gate dielectric layers 162 and the first gate electrodes 165A may be formed to fill the upper gap regions UR and the lower gap regions LR. The gate dielectric layers 162 may be formed to conformally cover inner surfaces of the upper gap regions UR and the lower gap regions LR. The first gate electrodes 165A may be formed to completely fill the upper gap regions UR and the lower gap regions LR, and then, removed by a predetermined depth from the upper portion of the upper gap regions UR together with the gate dielectric layers 162, and then, the gate capping layers 167 may be formed.

The first bonding insulating layer 192 may be formed on the first gate structures 160A, and the first source contact plugs 170A connected to the first source/drain regions 150A through the first bonding insulating layer 192 and the first interlayer insulating layer 190 may be formed. Together with the first source contact plugs 170A, or in a separate process, the first gate contact plugs 175A (see FIG. 3B) connected to the first gate electrodes 165A through the first bonding insulating layer 192 and the gate capping layers 167 may be formed.

The first interconnection line MI1 may be formed to penetrate through at least a portion of the first bonding insulating layer 192 from the upper surface and be connected to the first source contact plug 170A. The first interconnection line MI1 may be formed after removing a portion of the upper region of the first source contact plug 170A or may be formed to cover the upper end of the first source contact plug 170A. The first interconnection line MI1 may be formed together with the second interconnection line MI2 of FIG. 3B. As a result, the first semiconductor structure S1 may be manufactured.

Referring to FIG. 8E, a process for forming the second semiconductor structure S2 may start. On a base substrate 101′, the second channel structures 140B, place holder layers 130, the second source/drain regions 150B, and sacrificial gate structures 200′ may be formed.

First, the process described above with reference to FIG. 8A may be performed in the same manner. Although not specifically illustrated, an active region may also be formed in an upper region of the base substrate 101′. The sacrificial layers 118 and the first to fourth channel layers 141, 142, 143, and 144 may be alternately stacked on the base substrate 101′, and the sacrificial gate structures 200′ may be formed on the stack structure.

Next, the process described above is performed in the same manner with reference to FIG. 8B, but the base substrate 101′ is recessed relatively deeply on both sides of the sacrificial gate structures 200′, and before forming the second source/drain regions 150B, the place holder layers 130 may be further formed. For example, in order to form the place holder layers 130, separate sacrificial spacer layers may be formed within the recessed region formed by removing the sacrificial layers 118 and the first to fourth channel layers 141, 142, 143, and 144, and may be used.

The place holder layers 130 may be formed by growing from the base substrate 101′ by, for example, a selective epitaxial process. The place holder layers 130 may include a semiconductor material having a different composition from the second source/drain regions 150B. The second source/drain regions 150B may be formed by growing from the side surfaces of the second channel structures 140B, the base substrate 101,′ and the placeholder layers 130, for example, by a selective epitaxial process.

Referring to FIG. 8F, the second gate structures 160B may be formed, and the source connection plug SV may be formed.

First, the process described above with reference to FIG. 8C may be performed in the same manner to form the second interlayer insulating layer 196, and the sacrificial layers 118 and the sacrificial gate structure 200′ may be removed. Next, the process described above with reference to FIG. 8D may be performed in the same manner to form the second gate structures 160B, form the second bonding insulating layer 194, and form the second gate contact plugs 175B (see FIG. 3B) connected to the second gate electrodes 165B through the second bonding insulating layer 194 and the gate capping layers 167.

The source connection plug SV may be formed to be connected to one of the second source/drain regions 150B through the second bonding insulating layer 194 and the second interlayer insulating layer 196.

Referring to FIG. 8G, the first semiconductor structure S1 and the second semiconductor structure S2 may be bonded.

The first semiconductor structure S1 and the second semiconductor structure S2 may be connected by bonding the first bonding insulating layer 192 and the second bonding insulating layer 194 by annealing and/or applying pressure. The second semiconductor structure S2 may be turned upside down on the first semiconductor structure S1 so that the second bonding insulating layer 194 faces downwardly, and then bonding may be performed.

As the first semiconductor structure S1 and the second semiconductor structure S2 are bonded, the first interconnection line MI1 and the source connection plug SV may come into contact with and be electrically connected to one another.

Referring to FIG. 8H, in the bonding structure of the first semiconductor structure S1 and the second semiconductor structure S2, the base substrate 101′ may be removed and the base insulating layer 107 may be formed.

The base substrate 101′ may be partially removed by, for example, a lapping, grinding, and/or polishing process, so as to be thinned, and the remaining region may also be removed by an etching and/or oxidation process. In some embodiments, the base substrate 101′ may not be completely removed and may remain partially.

The base insulating layer 107 may be formed by depositing an insulating material in a region from which the base substrate 101′ was removed and performing a planarization process. In some embodiments, the base insulating layer 107 may be formed by oxidizing at least a portion of the base substrate 101′. The base insulating layer 107 may be formed to expose the place holder layers 130. The base insulating layer 107 may include, for example, silicon oxide.

Referring to FIG. 8I, the place holder layers 130 may be removed, and second source contact plugs 170B may be formed.

The place holder layers 130 exposed from the base insulating layer 107 may be selectively removed, and the second source contact plugs 170B may be formed to be connected to the second source/drain regions 150B. The second source contact plugs 170B may be formed after a portion of the second source/drain regions 150B is removed from the upper surface. In some embodiments, the second source contact plugs 170B may include regions having a shape corresponding to the place holder layers 130.

Next, referring to FIG. 3A, the third interlayer insulating layer 198 may be formed on the second source contact plugs 170B, and the upper interconnection lines 180 and the first upper contacts 182 may be formed sequentially. The second upper contacts 184 of FIG. 3B may be formed simultaneously with the first upper contacts 182 or may be formed in a separate process. The through-via FV of FIG. 3B may be formed to penetrate through the second semiconductor structure S2 in a separate process. As a result, the semiconductor device 100 of FIG. 3A may be manufactured.

According to an aspect of the present disclosed concepts, a method for manufacturing a semiconductor device includes: forming a first semiconductor structure including a first active structure extending in a first direction, first gate electrodes extending in a second direction, intersecting the first active structure and intersecting the first direction, a first bonding insulating layer on the first gate electrodes, first source contact plugs electrically connected to the first active structure, and an interconnection line connected to one of the first source contact plugs and extending in the first direction; forming a second semiconductor structure including a second active structure extending in the first direction, second gate electrodes intersecting the second active structure and extending in the second direction, a second bonding insulating layer disposed below the second gate electrodes and bonded to the first bonding insulating layer, and a source connection plug electrically connected to the second active structure; bonding the first bonding insulating layer and the second bonding insulating layer to bond the first semiconductor structure and the second semiconductor structure; and forming interconnection structures electrically connected to the second active structure and the second gate electrodes on the bonding structure of the first semiconductor structure and the second semiconductor structure, wherein, in the bonding, the interconnection line is connected to the source connection plug, and the interconnection line overlaps the first active structure in plan view.

In embodiments, the first active structure may include first source/drain regions and first channel structures alternately arranged in the first direction, and the second active structure may include second source/drain regions and second channel structures alternately arranged in the first direction.

In embodiments, the forming of the first semiconductor structure may include: alternately stacking first sacrificial layers and a plurality of first channel layers on a substrate; patterning a stacked structure of the first sacrificial layers and the plurality of first channel layers and an upper region of the substrate to form a preliminary active structure extending in the first direction; forming first sacrificial gate structures extending in the second direction on the preliminary active structure; removing a portion of the preliminary active structure from an outer side of the first sacrificial gate structures and forming first source/drain regions; removing the first sacrificial layers and the first sacrificial gate structures and forming first gate structures; forming the first bonding insulating layer on the first gate structures; forming the first source contact plugs to be connected to the first source/drain regions; and forming the interconnection line on one of the first source contact plugs.

In embodiments, the interconnection line may be formed to penetrate through at least a portion of the first bonding insulating layer from an upper surface.

In embodiments, the first gate structures may respectively include first gate electrodes, and the method may further include forming first gate contact plugs respectively connected to the first gate electrodes through the first bonding insulating layer.

In embodiments, the forming of the first semiconductor structure may include: alternatingly stacking second sacrificial layers and a plurality of second channel layers on a base substrate; forming second sacrificial gate structures extending in the second direction on a stack structure of the second sacrificial layers and the plurality of second channel layers; removing a portion of the stack structure from an outer side of the second sacrificial gate structures and forming place holder layers and second source/drain regions; removing the second sacrificial layers and the second sacrificial gate structures and forming second gate structures; forming the second bonding insulating layer on the second gate structures; and forming the source connection plug on one of the second source/drain regions.

In embodiments, the method may further include removing the base substrate after bonding the first semiconductor structure and the second semiconductor structure.

In embodiments, the method may further include depositing an insulating material in a region from which the base substrate was removed to form a base insulating layer; and removing the place holder layers.

In embodiments, the second gate structures may respectively include second gate electrodes, and the method may further include second gate contact plugs connected to the second gate electrodes through the second bonding insulating layer.

In embodiments, the interconnection line may overlap the second active structure in plan view.

By optimizing the arrangement of the interconnection structure electrically connecting the upper transistor to the lower transistor in a 3DSFET, the semiconductor device with improved integration and electrical characteristics may be provided.

The various advantages and effects of the present disclosed concepts are not limited to the above-described contents and will be more easily understood in the course of describing specific embodiments of the present disclosed concepts.

While embodiments have been illustrated and described above, it will be apparent to those skilled in the art that modifications and variations could be made without departing from the scope of the present disclosed concepts as defined by the appended claims.

What is claimed is:

1. A semiconductor device comprising:
a first semiconductor structure; and
a second semiconductor structure on the first semiconductor structure,
wherein the first semiconductor structure includes:
an active region extending in a first direction;
first gate electrodes extending on the active region in a second direction, intersecting the first direction;
a plurality of first channel layers spaced apart from one another on the active region in a third direction, substantially perpendicular to the first and second directions, and respectively surrounded by the first gate electrodes;
first source/drain regions connected to the plurality of first channel layers on both sides of the first gate electrodes;
a first bonding insulating layer on the first gate electrodes;
first source contact plugs connected to the first source/drain regions and extending in the third direction;
a first interconnection line extending through the first bonding insulating layer in the first direction and connected to one of the first source contact plugs; and
first gate contact plugs connected to the first gate electrodes and extending in the third direction, and
wherein the second semiconductor structure includes:
second gate electrodes extending in the second direction;
a plurality of second channel layers spaced apart from one another in the third direction and respectively surrounded by the second gate electrodes;
second source/drain regions connected to the plurality of second channel layers on both sides of the second gate electrodes;
a second bonding insulating layer disposed below the second gate electrodes and bonded to the first bonding insulating layer;
second source contact plugs connected to upper regions of the second source/drain regions and extending in the third direction;
a source connection plug connecting a lower region of one of the second source/drain regions to the first interconnection line and extending in the third direction through the second bonding insulating layer; and
second gate contact plugs connected to the second gate electrodes and the first gate contact plugs and extending in the third direction,
wherein a first active structure including the plurality of first channel layers and the first source/drain regions overlaps the first interconnection line in the third direction.

2. The semiconductor device of claim 1, wherein a second active structure including the plurality of second channel layers and the second source/drain regions overlaps the first interconnection line in the third direction.

3. The semiconductor device of claim 1, wherein the first gate electrodes and the second gate electrodes overlap one another in the third direction.

4. The semiconductor device of claim 3, wherein the first interconnection line extends between one of the first gate electrodes and one of the second gate electrodes.

5. The semiconductor device of claim 3, wherein the first gate contact plugs and the second gate contact plugs overlap the first gate electrodes and the second gate electrodes in the third direction.

6. The semiconductor device of claim 1, wherein the first gate contact plugs are respectively connected to upper surfaces of the first gate electrodes, and the second gate contact plugs are respectively connected to lower surfaces of the second gate electrodes.

7. The semiconductor device of claim 1, wherein:
the first semiconductor structure further includes a second interconnection line extending through the first bonding insulating layer in the second direction and connected to one of the first source contact plugs, and
the second semiconductor structure further includes a through-via extending in the third direction and connected to the second interconnection line through the second bonding insulating layer.

8. The semiconductor device of claim 7, wherein an upper end of the through-via is on a higher level than a level of upper ends of the second source contact plugs.

9. The semiconductor device of claim 7, wherein the second interconnection line extends outwardly of the first active structure in plan view.

10. The semiconductor device of claim 1, wherein the second semiconductor structure further includes a base insulating layer disposed on the plurality of second channel layers and filling a space between the second source contact plugs.

11. The semiconductor device of claim 1, wherein the first gate electrodes and the second gate electrodes are arranged to be substantially symmetrical, based on an interface between the first bonding insulating layer and the second bonding insulating layer.

12. The semiconductor device of claim 1, wherein the first source/drain regions include first conductivity-type impurities, and the second source/drain regions include second conductivity-type impurities.

13. A semiconductor device comprising:
first source/drain regions spaced apart from one another in a first direction;
first gate structures spaced apart from one another in the first direction and extending in a second direction, substantially perpendicular to the first direction;
second source/drain regions spaced apart from the first source/drain regions, respectively, in a third direction, substantially perpendicular to the first and second directions;
second gate structures spaced apart from the first gate structures, respectively, in the third direction and extending in the second direction; and
a source connection structure connecting one of the first source/drain regions and one of the second source/drain regions to one another,
wherein the source connection structure overlaps the second source/drain regions and the second gate structures in plan view.

14. The semiconductor device of claim 13, wherein the source connection structure overlaps the first source/drain regions and the first gate structures in plan view.

15. The semiconductor device of claim 13, wherein:
the first source/drain regions include first to third lower source/drain regions sequentially arranged in the first direction,
the second source/drain regions include first to third upper source/drain regions sequentially arranged in the first direction, and
the source connection structure connects an upper region of the third lower source/drain region and a lower region of the second upper source/drain region.

16. The semiconductor device of claim 15, wherein
the source connection structure includes:
a first source contact plug extending in the third direction on the third lower source/drain region and connected to the third lower source/drain region;
a source connection plug extending in the third direction below the second upper source/drain region and connected to the second upper source/drain region; and
an interconnection line connecting an upper end of the first source contact plug and a lower end of the source connection plug.

17. The semiconductor device of claim 13, wherein
the source connection structure includes:
a first source contact plug extending in the third direction on at least one of the first source/drain regions and connected to the first source/drain region; and
a source connection plug extending in the third direction through the second source/drain region on at least one of the second source/drain regions and connected to the first source contact plug.

18. A semiconductor device comprising:
a first semiconductor structure; and
a second semiconductor structure on the first semiconductor structure,
wherein the first semiconductor structure includes:
a first active structure extending in a first direction;
first gate electrodes intersecting the first active structure and extending in a second direction, intersecting the first direction; and
a first bonding insulating layer on the first gate electrodes, and
wherein the second semiconductor structure includes:
a second active structure extending in the first direction;
second gate electrodes intersecting the second active structure and extending in the second direction; and
a second bonding insulating layer disposed below the second gate electrodes and bonded to the first bonding insulating layer, and
the semiconductor device further comprising:
gate connection structures electrically connecting the first gate electrodes to the second gate electrodes, respectively; and
a source connection structure electrically connecting a region of the first active structure to a region of the second active structure,
wherein the source connection structure is disposed between the first active structure and the second active structure in a third direction, substantially perpendicular to the first direction and the second direction, and overlaps the first active structure and the second active structure in plan view.

19. The semiconductor device of claim 18, wherein the gate connection structures are arranged between the first gate electrodes and the second gate electrodes in the third direction, and overlap the first gate electrodes and the second gate electrodes in plan view.

20. The semiconductor device of claim 18, wherein the gate connection structures are connected to a side surface of the first gate electrodes and a side surface of the second gate electrodes in the second direction.
